(19) United States
(12) Patent Application Publication
(10) Pub. No.: US 2013/0209795 A1
(43) Pub. Date: Aug. 15, 2013

(54) POLYMER BACKSHEET OF SOLAR CELL ASSEMBLY AND MANUFACTURING PROCESS THEREOF

(71) Applicant: Xuexi Liu, Shanghai (CN)

(72) Inventor: Xuexi Liu, Shanghai (CN)

(73) Assignee: SUZHOU SUNSHINE NEW MATERIALS TECHNOLOGY CO., LTD., Suzhou, Jiangsu (CN)

(21) Appl. No.: 13/880,729

(22) PCT Filed: Oct. 18, 2011
(86) PCT No.: PCT/CN11/80877

§ 371 Date: Apr. 20, 2013

(30) Foreign Application Priority Data
Oct. 20, 2010 (CN) 201010512663.3

(51) Int. Cl. H01L 31/048; B32B 5/00; B29C 47/06; B32B 27/08

(52) U.S. Cl. CPC H01L 31/0487; B32B 27/08; B32B 5/00; B29C 47/067; B29C 47/061
USPC 428/337; 428/475.5; 428/521; 428/522; 428/412; 428/426; 428/475.8; 428/519; 428/520; 428/423.5; 428/424.8; 428/424.4; 428/421; 428/422; 264/173.12; 428/523; 428/522; 428/480

(57) ABSTRACT

A solar module polymer backsheet comprising a basement layer, tie layer on each side of the basement layer, a fourth film layer and a fifth film layer on the other side of the tie layer, the basement layer comprises at least one of the following components: polyamide polymers, polypropylene and propylene polymers, polyethylene and vinyl polymers, poly(vinylidene chloride), styrene polymers, ABS resins, liquid crystal polymers, acrylic polymers, polyphenylene oxides, polycarbonates, and polymer alloys of polycarbonates with poly(C₂₋₆ alkylene glycol phthalates). The manufacturing process of the backsheet was provided, one polymer or a mixture of more polymers are used to form the film configuration in place of the former PET layer, thus excellent processability, material mechanical performances, barrier property and ageing resistance can be obtained; furthermore, the laminated films of the backsheet are formed via melt co-extrusion or extrusion composite process, which significantly upgraded the adhesion strength between the laminated films, and simplified manufacturing process.

### FIELD OF THE INVENTION

The present invention relates to a solar module polymer backsheet, specifically to the polymer interlayers and tie layer of the polymer backsheet of a solar module, as well as the manufacturing process thereof

### BACKGROUND OF THE INVENTION

Currently the main energy source of mankind is originated from fossil fuel including oil, coal and natural gas, however, the fossil source will be depleted in the next one hundred years or so, and a great amount of carbon dioxide is emitted during the process of fossil fuel combustion, which has changed the atmosphere composition and deteriorated the global climate. The green regenerative energy without environment pollution becomes the only solution to deal with the energy challenge and to achieve the low-carbon emission. Solar power is one of the most important green regenerative energy. Various countries take the solar power as their national energy strategy, and are encouraging and pushing the development of solar power with great effort. In recent years, the rapid expansion of solar business in many countries has had the benefit of the support from their government and people's eagerness for green regenerative energy.

At present, power generation via solar cells is still facing big challenge. The problems are that the cost of power generation via solar cell is higher than that via traditional fossil fuels, and the environment pollution occurs in some processes during the manufacturing of solar cells and modules. The challenge of the development of power generation via solar cells lies in how to improve the existing manufacturing process and the design and preparation of relevant materials for solar cells and modules via technical innovation, thus to avoid environment pollution and reduce the cost of power generation via solar energy continuously.

Solar power technologies mainly comprise crystalline silicon (c-Si) solar cells and thin film solar cells. C-Si solar cells include mono-crystalline silicon and polycrystalline silicon, and thin film solar cells include amorphous silicon, crystallite silicon, CuInGaSe, CdTe, dye-sensitized and organic solar cells. No matter what sort of solar cell, solar modules have to be prepared to effectively protect and pack semiconductor cells for long term power generation with high efficiency. Taking the c-Si solar module as an example, normally low iron contained ultra-bright glass with about 3 mm thickness is used as the front panel of a solar module; two glue films of ethylene-vinyl acetate (EVA), the encapsulation material, are respectively placed on the top and bottom of the cell sheet, and a polymer multilayer laminated film is used as a backsheet. These layers are laminated via a vacuum lamination process at 140-150° C. to make a module, during this process, the EVA glue film adheres the cell sheet to the front panel glass and the backsheet. Moreover, polyvinyl butyral (PVB), polyethylene grafted with silanes and other materials are commonly used as an encapsulation material for solar modules as well.

The incoming sunlight from the front glass panel passes through the EVA glue film to reach the solar cell sheet and it is converted to electric energy. The transmittance of the glass is critical to ensure sufficient incident light to reach the cell sheet. The primary function of the backsheet is to protect the EVA glue film and the cell sheet to ensure the mechanical integrity, hydrolysis resistance, UV resistance and insulation property, and to reduce the penetration of moisture. In general, the backsheet is formed through the composition of multilayer films made of different polymers, thus the film layers made of different polymers can play a part in providing different protection functions mentioned above and the ageing resistant performance.

The adhesive strength between the backsheet and the EVA glue film, the adhesive strength between different polymer layers in the backsheet, and the ageing resistant performance of the polymer films used are key technical parameters to determine and affect the function of the backsheet and the performance of the solar modules.

In general, the backsheet of a solar cell comprises the following layers:
(1) fluoroplastics film (FP), e.g. polyvinyl fluoride (PVF) film from DuPont with the trade mark Tedlar®; polyvinylidene fluoride (PVDF) film from Akema with the trade mark of Kynar®;
(2) biaxial stretching polyethylene terephthalate (PET);
(3) EVA or polyolefin layer (PO);
(4) adhesive interlayers or tie coat (Tie) between two or three layers mentioned above, e.g. polyurethane adhesives.

The backsheet may have the structure of FP/Tie/PET/Tie/EVA, FP/Tie/PET/Tie/PO, or FP/Tie/PET/ Tie/FP.

The interlayer PET in common use has shown the following defects:
(1) poor melt strength, easy to trickle during processing;
(2) poor hydrolysis resistance, remarkable deterioration of mechanical properties occurs after ageing, easy to tear;
(3) poor adhesion to other polymer layers.

### SUMMARY OF THE INVENTION

Therefore, the technical problem that the present invention needs to solve is to provide a solar module polymer backsheet having novel interlayers that possess better process ability, material mechanical performance, barrier property and ageing resistance.

The invention provides a solar module polymer backsheet, comprising a basement layer, tie layer on each side of the basement layer, and a fourth film layer and a fifth film layer lying on the other two sides of the tie layer, said basement layer comprises at least one of the following components: polyamide polymers, polypropylene and propylene polymers, polyethylene and vinyl polymers, poly(vinylidene chloride), styrene polymers, ABS resins, liquid crystal polymers, acrylic polymers, polyphenylene oxides, polycarbonates, and polymer alloys of polycarbonates with poly(C₂₋₆ alkylene glycol phthalates).

The solar module polymer backsheet in accordance with the present invention is preferably that in which said polyamide is a polymer with a backbone containing an amide group.

Polyamide is a polymer with a backbone containing the amide group —CONH—, and it shows excellent mechanical properties, high surface activity, easy adhesion and good ageing resistance. Polyamide can be synthesized as per the following methods: condensation polymerization of binary amines and binary acids, condensation polymerization of amino acids, ring-opening polymerization of lactams, condensation polymerization of binary amines and diacyl chlorides, and reaction between diisocyanates and dicarboxylic acids. The polyamide polymers used in the present invention include any polymer with a backbone containing an amide group prepared by any synthesis methods mentioned above. The polyamide polymers are selected from: polyamide 6, polyamide 66, polyamide 46, polyamide 610, polyamide 612, polyamide 614, polyamide 613, polyamide 615, polyamide 616, polyamide 11, polyamide 12, polyamide 10, polyamide 912, polyamide 913, polyamide 914, polyamide 915, polyamide 616, polyamide 1010, polyamide 1012, polyamide 1013, polyamide 1014, polyamide 1210, polyamide 1212, polyamide 1213, polyamide 1214, adipamide terephthalate, polyadipamide terephthalate, pelargondiamide terephthalate, polypelargondiamide terephthalate, caprodiamide terephthalate, polycaprodiamide terephthalate, dodecandiamide terephthalate, polydodecandiamide terephthalate, adipamide adipate/adipamide terephthalate copolyamide, adipamide terephthalate/adipamide isophthalate copolyamide, meta-xylene amide adipate, polymeta-xylene amide adipate, adipamide terephthalate/2-methyl glutaramide terephthalate, adipamide adipate/adipamide terephthalate/adipamide isophthalate copolyamide, caprolactam—adipamide terephthalate, polycaprolactam—adipamide terephthalate, or the combination thereof.

The solar module polymer backsheet in accordance with the present invention is preferably that in which the polypropylene refers to polymers formed from the polymerizaton of propylene; the polypropylene polymers can be a mixture of polymers modified by the maleic anhydride graft, blended with other polymers, toughened with elastomers, and packed with fiberglass or inorganic filler.

The solar module polymer backsheet in accordance with the present invention is preferably that in which the polyethylene and the ethylene polymers include: high density polyethylene (HDPE), medium density polyethylene (MDPE), low density polyethylene (LDPE), linear low density polyethylene (LLDPE), ultra high molecular weight polyethylene (UHMWPE), metallocene LLDPE, crosslinked polyethylene, silane crosslinked polyethylene, chlorosulfonated polyethylene, chlorinated polyethylene, polyethylene oxide, ethylene-maleic anhydride copolymer, ethylene-alkyd ethylene copolymer, ethylene-vinyl alcohol copolymer, ethylene-methyl acrylate copolymer, ethylene-ethyl acrylate copolymer, ethylene-propyl acrylate copolymer, ethylene-butyl acrylate copolymer, ethylene-acrylate-acrylic acid ternary copolymer, ethylene-acrylic acid copolymer, ethylene-methacrylic acid copolymer, ethylene-acrylic acid ionic polymer, maleic anhydride graft polyethylene.

The solar module polymer backsheet in accordance with the present invention is preferably that in which the polystyrene refers to polymers formed from the polymerization of styrene, and various types of copolymeric and modified polystyrene, such as high impact polystyrene (HIPS), styrene-butadiene-styrene copolymer (SBS), hydrogenated styrene-butadiene-styrene copolymer (SEBS), styrene-maleic anhydride copolymer (SMA), etc.

Acrylic polymers include homopolymers, copolymers of acrylic acid, methacrylic acid and the esters thereof, as well as polymer blends having acrylic resins as the main component. In a preferred embodiment, the acrylic polymer is polymethyl methacrylate (PMMA).

ABS resins include copolymers of at least two monomers selected from acrylonitrile, butadiene, styrene, C₁₋₄ alkyl (meth)acrylate, vinyl chloride, ethylene, propylene, maleic anhydride and maleimide; and blends of ABS resins with other polymers, such as ABS/PMMA, ABS/PC, ABS/PVC, ABS/PA, ABS/PBT, and ABS/PET, etc.

Poly (vinylidene chloride) is a polymer of vinylidene chloride.

Liquid crystal polymers are preferably polymers of polyester liquid crystal polymers (LCP).

Polyphenylene oxide (PPO) is poly (2, 6-dimethyl-p-phenylene ether), or so-called phenylene ether.

Polycarbonate (bi-phenol A) is 2, 2′-bis (4-hydroxyphenyl) propane carbonate. The polymer alloys of polycarbonates with poly (C₂₋₆ alkylene glycol phthalates) are mainly blend alloys of polycarbonates with polyethylene glycol terephthalate, polypropylene glycol terephthalate and polybutylene glycol terephthalate, respectively.

In a preferred embodiment, the basement layer further comprises various kinds of inorganic fillers to upgrade the material mechanical performance, the thermal conduction and the fire retardance. The inorganic fillers afore-mentioned include, but not limited to: titanium oxide, silica, zinc oxide, mica, wollastonite, talc powder, zinc sulfide, calcium carbonate, barium sulfate, tungsten carbide, silicon carbide, boron nitride, montmorillonite, clay, fiberglass, micro glass beads, molybdenum sulfide, magnesia, alumina, perfluoro polyhedral siloxane and so forth. Furthermore, inorganic fillers may also include photo-stabilizer, thermo-stabilizer, antioxidant, plasticizer, coupling agent, slipping agent, fire retardant, hydrolysis resistant agent, light reflection and light scattering fillers, pigment and so forth.

Compatilizers and coupling agents can be added into the blends composed of two or more polymers afore-mentioned or the mixture filled with the inorganic fillers afore-mentioned.

In addition, for the blends composed of two or more polymers, the added compatilizers include but not limited to: polyethylene and vinyl copolymers thereof The vinyl copolymers can be copolymers of ethylene with at least one of the following monomers: vinyl acetate, C₁₋₄ alkyl acrylate, C₁₋₄ alkyl methacrylate, acrylic acid, methacrylic acid, maleic anhydride, glycidyl acrylate, glycidyl methacrylate; ionic polymers of ethylene-acrylic acid copolymer, ionic polymers of ethylene-methacrylic acid copolymer; polypropylene and propylene copolymers, maleic anhydride graft polypropylene, ethylene-propylene copolymer.

The surface of polymer film can be coated with metals, metal oxides and/or non-metallic oxides. The upper and lower surfaces of polymer film can be activated in various processes, of which the unrestrictive examples are priming coat, corona treatment, flame treatment, plasma treatment, silane coupling agent treatment, surface grafting, acid/alkali erosion activation, etc.

The polymer basement film can be formed via film processing processes such as extrusion casting, extrusion blow molding, rolling, biaxial stretching, etc., and also can be formed via co-extrusion with materials of other layers during the preparation of the backsheet. The polymer basement film according to the present invention has preferably a thickness from 50 to 500 μm, more preferably, from 150 to 200 μm.

Tie layer are preferably selected from one or more components of: polyethylene and vinyl copolymers, polypropylene and modified polypropylene, thermoplastic polyurethane, acrylic resins and ABS resins. These are different from the solvent-soluble adhesives used in the previous tie layer.

The present invention also provides a process for the manufacture of the afore-mentioned solar module backsheet, one layer or multiple layers of which is/are extruded via melt extrusion process.

The backsheet according to the present invention has a structure of laminated film:
It is preferred that at least one of the second and third tie layer is selected from at least one of the following polymer films: polyethylene and vinyl copolymers, polypropylene and modified polypropylene, thermoplastic polyurethane, acrylic resins and ABS resins. The tie layer are prepared via polymer melt extrusion process during the manufacturing of the laminated film of the backsheet.

The polyethylene material PE afore-mentioned include but not limited to the following types: LDPE, LLDPE, MDPE, HDPE, C₂-C₈ olefines graft PE or copolymers with ethylene, maleic anhydride graft PE, silane graft PE and so forth.

The vinyl copolymers refer to copolymers of ethylene with at least one monomer selected from vinyl acetate, C₁₋₄ alkyl (meth) acrylate, (meth) acrylic acid, maleic anhydride and glycidyl (meth) acrylate.

Modified polypropylene mainly refers to maleic anhydride graft modified polypropylene.

Thermoplastic polyurethane (TPU) afore-mentioned also includes mixtures of TPU with other polymers. Normally, TPU is formed via the reaction of polyester or polyether polyol, diisocyanates with small molecule glycol chain extension agents, and can be classified into polyester type, polyether type, etc. Examples of polyesters are apidate glycols such as polybutylene adipate glycol, polyethylene butylene adipate glycol. Examples of polyethers are polytetrahydrofuran glycol, polypropylene oxide glycol, polybutadiene glycol, etc. Normally, diisocyanates used in the invention are such as diphenylmethane-4, 4′-diisocyanate (MDI), toluene diisocyanate (TDI). The chain extension agent used are such as 1, 4-butanediol, 1, 6-butanediol, 2-methyl-1, 3-propanediol. TPU can be blended with various polymers, such as the afore-mentioned polyethylene and vinyl copolymers, polypropylene and modified polypropylene, as well as mixtures thereof with one or more polymer selected from polyacrylonitrile-butadiene-styrene copolymer (ABS), polycarbonates (PC), polyoxymethylene (POM), polyvinyl chloride (PVC), polystyrene (PS), polyacrylic ester (PMA), polymethyl methacrylate (PMMA), polyester resins, polystyrene-butadiene-styrene copolymer (SBS), chlorinated polyethylene (CPE) , etc.

Acrylic polymers are known collectively as acrylic resins, including the homopolymers, copolymers of acrylic acid, methacrylic acid and the esters thereof, as well as blends with acrylic resins as primary components, especially PMMA. Various types of silane coupling agents can be added into PE, vinyl copolymers, polypropylene and modified polypropylene, thermoplastic polyurethane or acrylic resins to improve the adhesion performance; and other active constituents used for activating the basement film surface can be added as well. These active constituents include acids and alkalis, such as hydroxides of alkali metals, e.g., sodium hydroxide, hydroxides of alkali-earth metals and boric acid, phosphoric acid, citric acid, etc.; sodium ammonium salts and sodium naphthalene salts; silicon tetrahalides; boranes; and other chemical constituents containing functional groups such as amino, carboxyl and sulfonic acid group.

The range of selecting ABS resins in the tie layer are same as the above, i.e. copolymers of at least two monomers selected from acrylonitrile, butadiene, styrene, C₁₋₄ alkyl (meth)acrylate, vinyl chloride, ethylene, propylene, maleic anhydride and maleimide; as well as blends of ABS resins with other polymers.

The fourth layer can be fluoroplastic film.

The fluoroplastic film can be formed via film processing processes such as extrusion casting, extrusion blow molding, rolling, biaxial stretching, etc., and can also be formed via co-extrusion with materials of other layers together during the preparation of the backsheet.

The fluoroplastic film has a thickness from 10 to 200 μm, preferably, from 15 to 50 μm.

### Layers of Aluminum Foil

In order to promote the obstruction of moisture, aluminum foils having a thickness from 5 to 50 μm, preferably from 10 to 20 μm can be added between individual layers. There is no specific limitation to the aluminum foils in the present invention, and they can be those conventionally used in the art. Aluminum foils adhere to other layers of the backsheet via tie layer by using extrusion lamination or coating process.

### The Fifth Layer

The materials of the fifth film layer can be selected from one of the following: fluoroplastics, polyolefines or olefin copolymers, and thermoplastic PU.

Polyolefines (POE), polyurethane (TPU) or fluoroplastics (FP), same as that in the fourth layer, is adhered to the basement layer via the third tie layer on the other surface of the basement layer. POE can be PE and vinyl copolymers, polypropylenes and modified polypropylenes, same as those in the second tie layer. Polyurethane (TPU) is also same as those in the second tie layer. Fluoroplastics are same as those selected for the fourth layer.

When polyolefines or thermoplastic polyurethane are used, the fifth layer material can be either single layer material, and the third tie layer also a single layer material, or the fifth layer combined with the third tie layer to be one layer.

The processing method of the fifth layer material is same as that of the second tie layer or the fourth fluoroplastic film.

The fifth layer has a thickness from 10 to 200 μm, preferably, from 20 to 100 μm.

The EVA glue film adheres the cell sheet to the front glass panel and the backsheet respectively, normally the fifth layer material of the backsheet is directly contacted with the EVA glue film, or the backsheet can be turned over to enable the fluoroplastics layer of the fourth layer be directly contacted with the EVA glue film.

Two typical multilayer film structures, FP(4)/Tie(2)/Nylon12(1)/Tie(3)/FP(5) and FP(4)/Tie(2)/Nylon12(1)/Tie(3) /POE(5), are now used to depict the process for preparing a multilayer film. On the premise that plastic granular materials are adopted in tie layer and melt extrusion process is used, five different ways are available to prepare the multilayer films: (i) starting from the plastic granulars, the five materials afore-mentioned are melt co-extruded via three or more extruders to prepare the backsheet having laminated films; (ii) fluoroplastic films FP(4) and FP(5) are prepared individually or purchased from the market, and the remaining three layers of fluoroplastic films and tie layer are composited with by passing the plastic granulars through a multi-extruder in a melt co-extrusion process to prepare the backsheet having the structure of multilayer films; (iii) Nylon12(1) films are prepared individually or purchased from the market, and the remaining four layers of fluoroplastic films and tie layer are composited with Nylon12(1) films at each side of the Nylon12(1) films in two steps, via two-layer co-extrusion composite process, to prepare the backsheet having the structure of multilayer films; (iv) fluoroplastic films, FP(4) and FP(5), and Nylon12(1) films are prepared individually or purchased from the market, and tie layer Tie(1) and Tie(2) are extruded and applied onto one side of the fluoroplastic films or each side of the Nylon12(1) films to prepare the backsheet having the structure of multilayer films in two steps, via extrusion composite process; while in case that the backsheet has the fifth layer of POE or TPU, POE or TPU is processed via melt extrusion process, either co-extruded with tie layer Tie(3) or extruded separately from tie layer Tie(3); (v) in the first step, Nylon12(1) film, tie layer Tie(3) and the fifth layer POE(5) are co-extruded through a multi-extruder into a laminated film with a three-layer structure, and in the second step, the tie layer Tie(2) adheres to the fluoroplastic film FP(4) via extrusion composite, or the fluoroplastic film FP(4) and the tie layer Tie(2) are co-extruded and composited with Nylon12(1)/Tie(3)/POE(5). Other co-extrusion or extrusion composite processes similar to the above five processes can also be used to prepare the backsheet with laminated films.

The laminated films according to the present invention are prepared via melt co-extrusion or melt extrusion composite process, and the basement film can be directly melt co-extruded with a tie layer, then melt composited with the fluoroplastic film, or the polymer basement film can be directly melt co-extruded with multi-layers of tie layer and fluoroplastic films to prepare the backsheet having laminated films. The sufficient contact and adhesion between every fluoroplastic film and tie layer and between these films and the polymer basement film in the status of melt results in a strong interlamellar bounding strength between the fluoroplastic layers and the polymer basement layer. It is shown in the T-type peeling test results that the bounding strength is as high as about 15 N/cm.

### ADVANTAGEOUS EFFECTS OF THE PRESENT INVENTION

According to the present invention, more than one polymers or a mixture of various polymers are used to form the film structure in place of the PET layers existing in the backsheet of a solar module, and either one layer or multi-layers of film can be used to replace the PET layers. When the films according to the present invention are used as the basement layer of the first layer, excellent processability, material mechanical performance, barrier property and ageing resistance can be obtained; furthermore, the laminated films of the backsheet are formed via melt co-extrusion or extrusion composite process, which significantly upgraded the adhesion strength between the laminated films, simplified the manufacturing process and reduced the manufacturing cost remarkably as well.

### BRIEF DESCRIPTION OF THE DRAWINGS

FIG. 1 is a schematic view of the combination layers in the backsheet of the solar module of the invention.

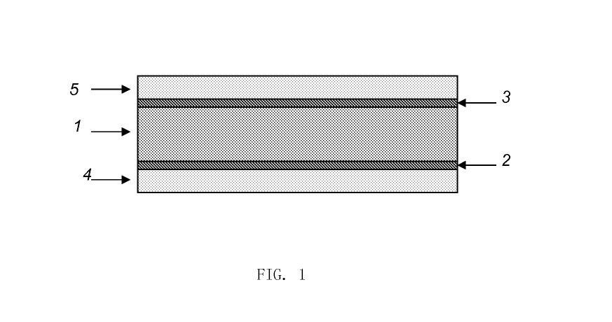

In FIG. 1, 1-5 indicate successively layers from the first one to the fifth one, wherein the second layer and the third layer are tie layer of the invention, the first layer is a basement layer, the fourth layer is a fluoroplastics film, and the fifth layer is a fluoroplastics film layer or a polyurethane layer.

### DESCRIPTION OF THE PREFERRED EMBODIMENTS OF THE INVENTION

Test Methods in the Preferred Embodiments

1) The Peeling Strength Between the Nylon Basement Layer and the Fluoroplastic Film in the Backsheet of a Solar Module

The laminated film is cut into sample strips, each with a 2 cm width and a 10 cm length, then the basement layer and the fluoroplastic film is immobilized in the upper and lower clamps of a tensile testing machine and the peeling test is performed in a speed of 10 cm/min.

2) The Peeling Strength Between the Backsheet of the Solar Module and the Ethylene-Vinyl Acetate Copolymer Encapsulation Material

The laminated film of the backsheet, EVA and the ultra-bright glass are laid up from bottom to top in the order and laminating pressed in a vacuum laminating machine in the temperature up to 145° C. for 10 min. The sample thus prepared is cut into sample strips with a 2 cm width and a 10 cm length. The sample strip is torn with hands to form a small opening, then immobilized between the upper and lower clamps of a tensile testing machine. The peeling strength is tested in a stretching velocity of 10 cm/min.

3) The Hydrothermal Ageing Test of the Backsheet

The laminated film of the backsheet, EVA and the ultra-bright glass are laid up from bottom to top in the order and laminating pressed in a vacuum laminating machine in the temperature up to 145° C. for 10 min. The glass/EVA/backsheet sample thus prepared is placed in a hydrothermal environment box and tested for 1000 hr. under 85° C./85% RH according to the standard IEC 61215. Samples are taken out of the box and the yellowing coefficient (ΔYI) of each sample is measured with a spectrophotometer.

4) The UV Ageing Test of the Backsheet

The laminated film of the backsheet, EVA and the ultra-bright glass are laid up from bottom to top in the order and laminating pressed in a vacuum laminating machine in the temperature up to 145° C. for 10 min. The glass/EVA/backsheet sample thus prepared is placed in a QUV ultraviolet ageing box and tested for 1000 hr. according to the standard IEC 61215. Samples are taken out of the box and the yellowing coefficient (ΔYI) of each sample is measured with a spectrophotometer.

### Comparison Example 1

Kynar®PVDF film (from Akema Co.) with a thickness of 30 μm; common PET biaxial stretching film with a thickness of 200 μm, common LLDPE film, PU solvent type adhesive and ethyl acetate, as a solvent, were used. The PU adhesive was applied, in two steps, onto each side of the PET film via adhesive composite process, and thus formed composite was composited with the PVDF film and the LLDPE film to form PVDF/Tie/PET/Tie/LLDPE laminated film backsheet, wherein the bond layers have a thickness of about 10 μm.

The peeling strength between the PVDF layer and the PET layer in the backsheet was measured as 4 N/cm.

Samples were made by using the backsheet with EVA and the glass via vacuum laminating press process, and the peeling strength between the backsheet and EVA encapsulating layer was measured as 58 N/cm.

The hydrothermal ageing test was conducted on the composite sample of glass/EVA/the backsheet afore-mentioned for 1000 hrs, to obtain the result: ΔYI=0.9.

The UV ageing test was conducted on the composite sample of glass/EVA/the backsheet afore-mentioned for 1000 hrs, to obtain the result: ΔYI=1.6.

### Example 1

15% of PMMA and 5% of surface-treated TiO₂, based on the weight of regular extrusion grade PVDF plastic granules, were added to regular extrusion grade PVDF plastic granules, and the mixture was extruded at about 200° C. in a twin-screw extruder to obtain PVDF blend plastic pellets. Ethylene-butyl acrylate (EBA) was used as the first tie layer, 5% of TiO₂, 1% of silane coupling agent, 0.5% of photo stabilizer and ant ageing agent were added and mixed homogeneously in a conventional mixing machine to obtain the EBA mixture. Regular Nylon 12 was used as the basement material.

The mixture of PVDF, Nylon 12 and EBA was melt co-extruded via a multi-layer extruder at a temperature of 270° C. to obtain a four-layer laminated film of PVDF/EBA/Nylon 12/EBA with the individual thickness of each layer as 20/20/200/80 μm.

The resultant solar module backsheet of PVDF/EBA/Nylon 12/EBA has a total thickness of 320 μm.

The peeling strength between the PVDF layer and the Nylon 12 layer of the backsheet was measured as 11 N/cm.

The backsheet, EVA and glass were composited in a vacuum laminating machine at 145° C. for 10 minutes to make the sample.

The peeling strength between the backsheet and the EVA encapsulating layer is measured as 65 N/cm.

The hydrothermal ageing test was conducted on the composited sample of glass/EVA/the backsheet afore-mentioned for 1000 hrs, to obtain the result: ΔYI=0.2.

The UV ageing test was conducted on the composited sample of glass/EVA/the backsheet afore-mentioned for 1000 hrs, to obtain the result: ΔYI=0.5.

### Example 2

5% of PMMA and 5% of surface-treated TiO₂ were added to regular extrusion grade PVDF plastic granules, and the mixture was extruded and pelletized at about 200° C. in a twin-screw extruder to obtain PVDF blend plastic pellets. Ethylene-butyl acrylate (EBA) and PMMA were used as tie layer, and regular Nylon 12 was used as the basement material.

PVDF, PMMA, EBA and Nylon 12 were melt co-extruded via four extruders at a temperature of 270° C. to obtain a seven-layer laminated film of PVDF/PMMA/EBA/Nylon12/EBA/PMMA/ PVDF with the individual thickness of each layer of 20/20/20/200/20/20/20 μm. The resultant solar module backsheet of PVDF/PMMA/EBA/Nylon12/EBA/PMMA/EBA/PVDF has a total thickness of 320 μm.

The peeling strength between the PVDF layer and the Nylon 12 layer of the backsheet was measured as 15 N/cm.

The backsheet, EVA and glass was composited in a vacuum laminating machine at 145° C. for 10 minutes to make the sample.

The peeling strength between the backsheet and the EVA encapsulating layer is measured as 65 N/cm.

The hydrothermal ageing test was conducted on the composited sample of glass/EVA/the backsheet above-mentioned for 1000 hrs, to obtain the result: ΔYI=0.2.

The UV ageing test was conducted on the composited sample of glass/EVA/the backsheet above-mentioned for 1000 hrs, to obtain the result: ΔYI=0.2.

5% of surface-treated TiO₂ was added to regular extrusion grade tetrafluoroethylene-hexafluoroethylene copolymer fluorinated plastic (FEP) granules, and the mixture was then extruded at about 360° C. by a twin-screw extruder to form a casting film with a thickness of 20 μm. A thermoplastic polyurethane (TPU) blend was used as the bonding line. A TPU blend was obtained by adding 1% of silane coupling agent, 30% of ethylene-butyl acrylate (EBA) and 0.5% of photo stabilizer and ant ageing agent into the TPU, and then homogeneously mixing it in a conventional mixing machine and extruding it via a twin-screw extruder for blending and pelletization.

Nylon 12 was melting blended with 50% of polypropylene (PP), and then 5% of maleic anhydride graft polypropylene (MAH-PP) was added as a compatibilizer. The mixture thus obtained was extruded and pelletized in a twin-screw extruder to obtain a nylon blend.

The Nylon 12 blend was melt co-extruded with the TPU blend via a multi-layer extruder to form a three-layer laminated film of TPU/Nylon 12/TPU onto the FEP film, and then the TPU and the FEP were composited via roll pressing to obtain the FEP/TPU/Nylon 12/TPU laminated film backsheet with the individual thickness of each layer of 20/20/200/80 μm.

The resultant solar module backsheet of FEP/TPU/Nylon 6/TPU has a total thickness of 320 μm.

The peeling strength between the FEP layer and the Nylon 12 layer of the backsheet was measured as 9 N/cm.

The backsheet was composited with the EVA and glass in a vacuum laminating press at 145° C. for 10 minutes to make the sample.

The peeling strength between the backsheet and the EVA encapsulating layer is measured as 56 N/cm.

The hydrothermal ageing test was conducted on the composited sample of glass/EVA/the backsheet above-mentioned for 1000 hrs, to obtain the result: ΔYI=0.3.

The UV ageing test was conducted on the composited sample of glass/EVA/the backsheet above-mentioned for 1000 hrs, to obtain the result: ΔYI=0.5.

### Example 4

5% of surface-treated TiO₂ was added to regular extrusion grade polychlorotrifluoroethylene (PCTFE) plastic granules, and the mixture was extruded and pelletized at about 200° C. in a twin-screw extruder to obtain PCTFE blend plastic pellets. Ethylene-butyl acrylate (EBA) was used as the first tie layer. 5% of TiO₂, 1% of silane coupling agent and 0.5% of photo stabilizer and ant ageing agent were added and mixed homogeneously in a conventional mixing machine to obtain the EBA mixture. Regular Nylon 12 was used as the basement material.

The mixture of Nylon 12 and EBA was melt co-extruded via a multi-layer extruder at a temperature of 270° C. to obtain the two-layer laminated film of Nylon 12/EBA with the individual thickness of each layer as 200/80 μm.

The mixture of PCTFE plastic granules and EBA was melt co-extruded at a temperature of 270° C. via a two-layer extruder onto the prepared Nylon 12/EBA two-layer laminated film, and then composited via roll pressing to obtain the PCTFE/EBA/Nylon 12/EBA four-layer laminated film with the individual thickness of each layer of 20/20/200/80 μm.

The resultant solar module backsheet of PCTFE/EBA/Nylon12/EBA has a total thickness of 320 μm.

The peeling strength between the PCTFE layer and the Nylon 12 layer of the backsheet was measured as 13 N/cm.

The backsheet was composited with EVA and glass in a vacuum laminating machine at 145° C. for 10 minutes to make the sample.

The peeling strength between the backsheet and the EVA encapsulating layer is measured as 65 N/cm.

The hydrothermal ageing test was conducted on the composited sample of glass/EVA/the backsheet above-mentioned for 1000 hrs, to obtain the result: ΔYI=0.2.

The UV ageing test was conducted on the composited sample of glass/EVA/the backsheet above-mentioned for 1000 hrs, and the result is: ΔYI=0.5.

### Example 5

30-60 parts by weight of polycaprolactam and 30-60 parts by weight of polypropylene were used as the basement material, and 10% of ethylene-ethyl acrylate copolymer based on the total weight was added as a compatibilizer.

Materials and preparation processes for the rest of layers are as same as those in Example 1. Satisfactory peel strength can still be achieved. The basement layer has a thickness of 250 μm.

### Example 6

5-10 parts by weight of styrene-butadiene-styrene copolymer, 10-20 parts by weight of polyethylene and 65-80 parts by weight of polyphenylene oxide (PPO) were used as basement materials, and 5% of maleic anhydride graft polyethylene based on the total weight was used as a compatibilizer.

Materials and preparation processes for the rest of layers are as same as those in Example 1. Satisfactory peel strength can still be achieved. The basement layer has a thickness of 220 μm.

### Example 7

15-35 parts by weight of acrylonitrile-ethylene copolymer, 10-50 parts by weight of PMMA, 40-60 parts by weight of LDPE and 30-50 parts by weight of PPO were used as basement materials, and 6% of acrylic acid base on the total weight was added as a compatibilizer.

Materials and preparation processes for the rest of layers are as same as those in Example 1. Satisfactory peel strength can still be achieved. The basement layer has a thickness of 100 μm.

### Example 8

40-60 parts by weight of polycarbonates, 30-50 parts by weight of polypropylene glycol terephthalate were used as basement materials, and 10% of methyl methacrylate-butadiene-styrene graft copolymer based on the total weight was added as a compatibilizer.

Materials and preparation processes for the rest of layers are as same as those in Example 1. Satisfactory peel strength can still be achieved. The basement layer has a thickness of 200 μm.

As shown in the above comparative example and examples, the basement layer of nylon or the polymer blends thereof can be melt co-extruded with fluoroplastic granules and plastics granules of the bonding lines via multi-layer extruder to form a laminated film backsheet, or nylon or polymer blends thereof can be melt co-extruded with bonding lines and further composited with fluoroplastic films via multi-layer extruder to form a laminated film backsheet. Thus, higher adhesion strength between the fluoroplastic films and the nylon films can be effectively achieved and the use of solvent adhesives can be completely averted to minimize the pollution resulting from the volatilization and emission of organic solvents. The effective adhesion with EVA encapsulating materials, in the solar modules, is provided by the application of TPU or polyolefin copolymers via extruding onto the other side of the nylon films. The laminated backsheet materials manufactured in this way have shown excellent ageing resistance performances.

1. A solar module polymer backsheet, comprising a basement layer, tie layer on each side of the basement layer, and a fourth film layer and a fifth film layer on the other two sides of the tie layer, wherein said basement layer comprises at least one of the following components: polyamide polymers, polypropylene and propylene polymers, polyethylene and vinyl polymers, poly(vinylidene chloride), styrene polymers, ABS resins, liquid crystal polymers, acrylic polymers, polyphenylene oxides, polycarbonates, and polymer alloys of polycarbonates with poly(C₂₋₆ alkylene glycol phthalates).

2. The solar module polymer backsheet according to claim 1, wherein said polyamide polymer is a polymer with a backbone containing an amide group.

3. The solar module polymer backsheet according to claim 1, wherein said polyamide polymers are selected from: polyamide 6, polyamide 66, polyamide 46, polyamide 610, polyamide 612, polyamide 614, polyamide 613, polyamide 615, polyamide 616, polyamide 11, polyamide 12, polyamide 10, polyamide 912, polyamide 913, polyamide 914, polyamide 915, polyamide 616, polyamide 1010, polyamide 1012, polyamide 1013, polyamide 1014, polyamide 1210, polyamide 1212, polyamide 1213, polyamide 1214, adipamide terephthalate, polyadipamide terephthalate, pelargondiamide terephthalate, polypelargondiamide terephthalate, caprodiamide terephthalate, polycaprodiamide terephthalate, dodecandiamide terephthalate, polydodecandiamide terephthalate, adipamide adipate/adipamide terephthalate copolyamide, adipamide terephthalate/adipamide isophthalate copolyamide, meta-xylene amide adipate, polymeta-xylene amide adipate, adipamide terephthalate/2-methyl glutaramide terephthalate, adipamide adipate/adipamide terephthalate/adipamide isophthalate copolyamide, caprolactam—adipamide terephthalate, polycaprolactam—adipamide terephthalate or the combination thereof.

4. The solar module polymer backsheet according to claim 1, wherein said polypropylene refers to polymers formed from the polymerizaton of propylene; said polypropylene polymers are mixtures of the polymers modified by the maleic anhydride graft, blended with other polymers, toughened with elastomers, and packed with fiberglass or inorganic filler.

5. The solar module polymer backsheet according to claim 1, wherein said polyethylene and the ethylene polymers are selected from: high density polyethylene (HDPE), medium density polyethylene (MDPE), low density polyethylene (LDPE), linear low density polyethylene (LLDPE), ultra high molecular weight polyethylene, metallocene LLDPE, crosslinked polyethylene, silane crosslinked polyethylene, chlorosulfonated polyethylene, chlorinated polyethylene, polyethylene oxide, ethylene-maleic anhydride copolymer, ethylene-alkyd ethylene copolymer, ethylene-vinyl alcohol copolymer, ethylene-methyl acrylate copolymer, ethylene-ethyl acrylate copolymer, ethylene-propyl acrylate copolymer, ethylene-butyl acrylate copolymer, ethylene-acrylate-acrylic acid ternary copolymer, ethylene-acrylic acid copolymer, ethylene-methacrylic acid copolymer, ethylene-acrylic acid ionic polymer, and maleic anhydride graft polyethylene.

6. The solar module polymer backsheet according to claim 1, wherein said styrene polymers are selected from polymers formed from the polymerization of styrene, and various types of copolymeric and modified polystyrene.

7. The solar module polymer backsheet according to claim 1, wherein said acrylic polymers are selected from homopolymers, copolymers of acrylic acid, methacrylic acid and the esters thereof, and polymer blends having acrylic resins as the main component.

8. The solar module polymer backsheet according to claim 7, wherein said acrylic polymer is polymethyl methacrylate (PMMA).

9. The solar module polymer backsheet according to claim 1, wherein said ABS resins are selected from the copolymers of at least two monomers selected from acrylonitrile, butadiene, styrene, C₁₋₄ alkyl acrylate, C₁₋₄ alkyl (meth) acrylate, vinyl chloride, ethylene, propylene, maleic anhydride and maleimide, and blends of ABS resins with other polymers.

10. The solar module polymer backsheet according to claim 1, wherein said basement layer further comprises an inorganic filler.

11. The solar module polymer backsheet according to claim 1, wherein said basement layer further comprises a compatibilizer and/or a coupling agent when the basement layer comprises two or more components.

12. (canceled)

13. (canceled)

14. The solar module polymer backsheet according to claim 1, wherein said basement layer has a thickness from 50 to 500 μm.

15. The solar module polymer backsheet according to claim 14, wherein said basement layer has a thickness from 150 to 250 μm.

16. The solar module polymer backsheet according to claim 1, wherein said tie layer are selected from one or more components selected from polyethylene and vinyl copolymers, polypropylene and modified polypropylene, thermoplastic polyurethane, acrylic resins and ABS resins.

17. The solar module polymer backsheet according to claim 1, wherein said fourth film layer is a fluoroplastic film.

18. The solar module polymer backsheet according to claim 1, wherein said fifth film layer is selected from one of fluoroplastics, polyolefines or olefin copolymers, and thermoplastic polyurethane.

19. A process for preparing the solar module polymer backsheet comprising a step of melting extrusion by which one or more layers of the solar module polymer backsheet is/are extruded.

20. The solar module polymer backsheet according to claim 10, wherein said basement layer further comprises a compatibilizer and/or a coupling agent when the basement layer comprises two or more components.

21. The solar module polymer backsheet according to claim 20, wherein said compatibilizer is selected from polyethylene and vinyl copolymers.

22. The solar module polymer backsheet according to claim 21, wherein said vinyl copolymers are the copolymers of ethylene with at least one of the following monomers: vinyl acetate, C₁₋₄ alkyl acrylate, C₁₋₄ alkyl methacrylate, acrylic acid, methacrylic acid, maleic anhydride, glycidyl acrylate, glycidyl methacrylate; ionic polymers of ethylene-acrylic acid copolymer, ionic polymers of ethylene-methacrylic acid copolymer; polypropylene and propylene copolymers, maleic anhydride graft polypropylene, and ethylene-propylene copolymer.
